(19) United States
(12) Patent Application Publication
(10) Pub. No.: US 2006/0231835 A1
(43) Pub. Date: Oct. 19, 2006

(54) Semiconductor device including ROM interface pad

(75) Inventors: Jin-Hyeok Choi, Yongin-si (KR); Sam-Yong Bahng, Seongnam-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/398,313

(22) Filed: Apr. 5, 2006

(30) Foreign Application Priority Data
Apr. 13, 2005 (KR) 10-2005-0030739

(51) Int. Cl. H01L 23/58

(52) U.S. Cl. 257/48; 257/E23.02; 257/E23.179

(57) ABSTRACT

A semiconductor device comprises a multilayer formed on a semiconductor substrate, the multilayer including a first circuit pattern, a second circuit pattern for testing the semiconductor device, the second circuit formed on a predetermined region of the multilayer, an inter-metal insulating layer formed on the second circuit pattern, a plurality of via contacts formed in the inter-metal insulating layer, and a plurality of ROM interface pads disposed on the inter-metal insulating layer, wherein the plurality of ROM interface pads are electrically connected with the second circuit pattern through the plurality of via contacts, and are separated from one another.

### CROSS-REFERENCE TO RELATED PATENT APPLICATION

This application claims priority to Korean Patent Application No. 10-2005-0030739, filed on Apr. 13, 2005, the disclosure of which is incorporated by reference herein in its entirety.

### BACKGROUND OF THE INVENTION

1. Technical Field

The present disclosure relates to a semiconductor device, and more particularly, to a semiconductor device operating in response to command codes stored in a read only memory (ROM).

2. Discussion of the Related Art

A central processing unit (CPU) or a microprocessor unit (MPU) operates in response to a series of commands. The commands, which are inputted by a user or a manufacturer in advance, are referred to as command codes. Generally, the command codes are stored in a memory device formed on a semiconductor chip.

The command codes can be stored in a non-volatile read only memory (ROM), wherein stored values are retained after power is turned off. The data stored in some ROMs can be altered. These ROMs include an erasable programmable ROM (EPROM), an electrically erasable programmable ROM (EEPROM), or a flash ROM formed on a semiconductor chip. Command codes stored in these ROMs can be edited, but erasable ROM manufacture is complex and the space occupied by the ROM and related components is large as compared to memories other than erasable ROMs.

A mask ROM can be fabricated in a small-sized chip using a simple fabrication process. Further, testing procedures are simpler. However, the conventional mask ROM requires a ROM code that must be prepared in development stages, and a photo mask is used to input command codes into the ROM. Each time the command codes are edited, an editing mask for reflecting the edited command codes must be made, and a new mask ROM needs to be made using the editing mask. Accordingly, if errors occur when the command codes are edited, the editing mask must be changed and another verifying process must be performed.

An alternative approach is to use an external memory device that is separate from the chip to store command codes. An external ROM interface is needed to connect the chip to the external memory device. The chip executes the edited command codes stored in the external memory device through the external ROM interface. The validity of command codes to be edited can be verified based on results from executing the edited command codes.

To use the external ROM interface as a path for the command codes stored in the ROM, data I/O pads, address pads, and control pads are additionally required.

To process a large amount of data quickly, the CPU data bus width can be widened. When the data bus width increases from 32 bits to 64 bits, the number of I/O pads increases from 32 to 64. Also, when a ROM address or a control signal is considered, more address pads or control pads are needed. For consistent performance, additional pads should have the same characteristics as the existing pads, such as, for example, good electrostatic discharge (ESD) and good driving ability. Also, the additional pads used for the external ROM interface occupy an additional space inside the chip. Thus, the size of the chip increases.

### SUMMARY OF THE INVENTION

Exemplary embodiments of the present invention include a semiconductor device including a ROM interface pad that does not occupy a separate space in a chip.

Exemplary embodiments of the present invention include a semiconductor device where a vertical structure used for verifying command codes stored in a ROM is different in a test stage and a mass-production stage.

According to an embodiment of the present invention, a semiconductor device comprises a multilayer formed on a semiconductor substrate, the multilayer including a first circuit pattern, a second circuit pattern for testing the semiconductor device, the second circuit formed on a predetermined region of the multilayer, an inter-metal insulating layer formed on the second circuit pattern, a plurality of via contacts formed in the inter-metal insulating layer, and a plurality of ROM interface pads disposed on the inter-metal insulating layer, wherein the plurality of ROM interface pads are electrically connected with the second circuit pattern through the plurality of via contacts, and are separated from one another.

According to an embodiment of the present invention, a semiconductor device having a plurality of pads for receiving a voltage, a control signal, and input/output data from outside, the semiconductor device comprising a processor unit formed using a plurality of layers on a substrate, a test circuit block formed using the plurality of layers, the test circuit block receiving test data from a predetermined data storage device located outside of the semiconductor device and transferring the test data to the processor unit, an inter-metal insulating layer formed on the test circuit block and comprising a plurality of via contacts, and a plurality of ROM interface pads disposed on the inter-metal insulating layer, wherein the plurality of ROM interface pads are electrically connected to the test circuit block through the plurality of via contacts, and are separated from one another.

According to an embodiment of the present invention, a test printed circuit board (PCB) comprises an external memory device storing command codes to be verified, and a semiconductor device comprising a processor device receiving the command codes of the external memory device and validating the command codes, wherein the semiconductor device and the external memory device are mounted on the test PCB, and the external memory device is electrically connected to the test PCB.

According to an embodiment of the present invention, a semiconductor device comprises a multilayer formed on a semiconductor substrate, the multilayer including a first circuit pattern for performing a predetermined function, a second circuit pattern for testing the semiconductor device formed on a predetermined region of the multilayer, an inter-metal insulating layer formed on the second circuit pattern, a plurality of via contacts formed on the inter-metal insulating layer, a first metal layer formed on a pad metal layer in a pad region and a plurality of ROM interface pads disposed on the inter-metal insulating layer, wherein the ROM interface pads are electrically connected to the second circuit pattern through the plurality of via contacts, and separated from one another.

### BRIEF DESCRIPTION OF THE DRAWINGS

Exemplary embodiments of the present invention can be understood in more detail from the following description taken in conjunction with the accompanying drawings in which:

FIG. 1 is a sectional view illustrating a vertical structure of a semiconductor device including a ROM interface pad in a test stage according to an embodiment of the present invention;

FIG. 2 is a perspective view of the semiconductor device in FIG. 1;

FIG. 3 is a sectional view illustrating a vertical structure of a semiconductor device in a mass-production stage, according to an embodiment of the present invention;

FIG. 4 is a perspective view of the semiconductor device in FIG. 3;

FIG. 5 is a circuit diagram used to test the semiconductor device shown in FIG. 1 in a test stage according to an embodiment of the present invention;

FIG. 6 is a circuit diagram used to test the semiconductor device shown in FIG. 1 in a test stage according to another embodiment of the present invention;

FIG. 7 is a circuit diagram illustrating a Printed Circuit Board (PCB) used to verify command codes for a semiconductor device when the semiconductor device is not assembled according to an embodiment of the present invention;

FIG. 8 is a circuit diagram illustrating a PCB used to verify command codes for a semiconductor device in a packaged state according to an embodiment of the present invention; and

FIG. 9 is a sectional view of a semiconductor device including a ROM interface pad in a test stage according to another embodiment of the present invention.

### DETAILED DESCRIPTION OF EXEMPLARY EMBODIMENTS

Exemplary embodiments of the present invention are more fully described below with reference to the accompanying drawings. The present invention may be embodied in many different forms and should not be construed as limited to the embodiments set forth herein.

A validation process of command codes that are stored in an external memory device begins by relaying the command codes to a semiconductor device and operating the semiconductor device in response to the relayed command codes. Here, the semiconductor device denotes a semiconductor chip that includes a processor such as, for example, a CPU or MPU that operates in response to the command codes. In the validation process, the semiconductor device is operated under preset conditions, e.g., parameters such as an operating voltage, operating speed, temperature are preset. The operating parameters are known to a designer during the design stage of the semiconductor device.

An external interface pad disposed on the semiconductor device is used when developing command codes. The validation of command codes is performed in the initial stage of product development or to overcome packaging problems. According to an embodiment of the present invention, during a testing stage, a simple test pad fulfilling the minimal electrical requirements is formed and used, and such test pads are removed during a mass-production stage. Therefore, no new processes are used during the transition from the test stage to the mass-production stage.

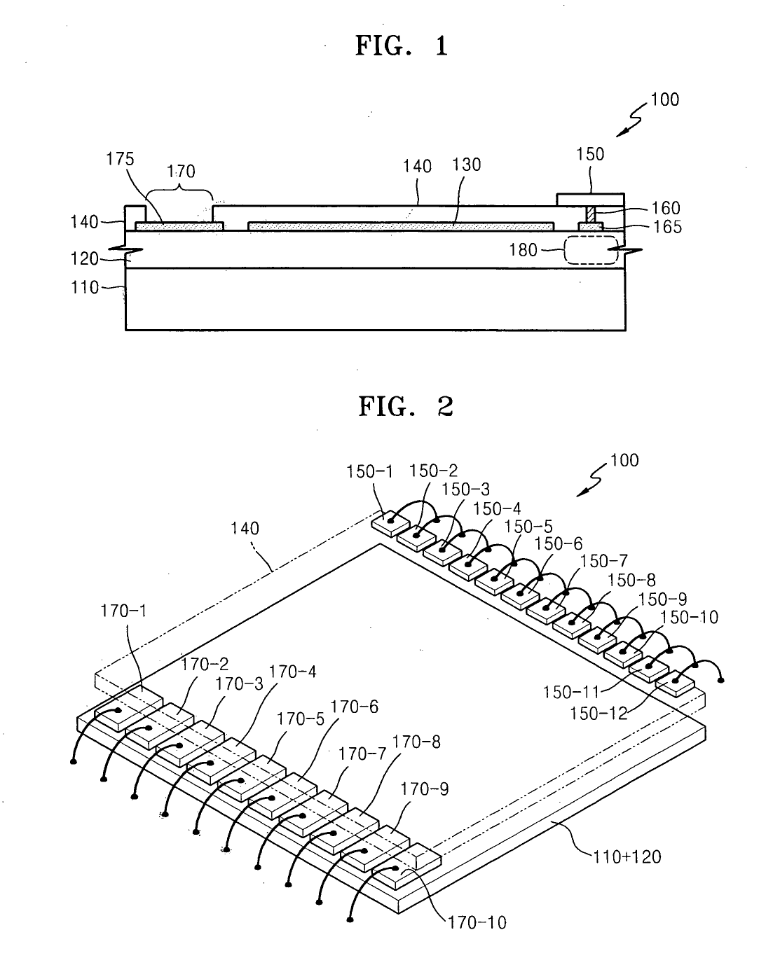

FIG. 1 is a sectional view illustrating a vertical structure of a semiconductor device 100 including a ROM interface pad in a test stage according to an embodiment of the present invention.

Referring to FIG. 1, the semiconductor device 100 includes a substrate 110, a multilayer 120, a metal layer 130, an inter-metal insulating layer 140, a ROM interface pad 150, a via contact 160, a test pad metal layer 165, a pad region 170, a pad metal layer 175 and a test circuit region 180.

The multilayer 120 includes a plurality of layers comprising deposited layers of various materials and insulating layers interposed between the deposited layers for blocking the flow of electrical current between layers. Circuit patterns (not shown) performing a predetermined function of the semiconductor device are formed on the multilayer 120.

The metal layer 130 is an electrical connection between the circuit patterns (not shown) formed on the multilayer 120. The test pad metal layer 165 is an input/output terminal for test circuit patterns (not shown) included in the test circuit region 180, and the pad metal layer 175 is an input/output terminal for the circuit patterns performing a predetermined function of the semiconductor device.

The ROM interface pad 150 is electrically connected to the test circuit pattern (not shown). The ROM interface pad 150 is a transmitting path for signals requesting test data stored in an external memory device (not shown) and a receiving path for the test data. The ROM interface pad 150, comprising, for example, a metal layer used for testing purposes, is electrically connected to the test pad metal layer 165 through the via contact 160. A plurality of ROM interface pads 150 may be formed to correspond to the number of parallel signals, and the ROM interface pads are electrically separated from one another.

Because the test pad metal layer 165 and the pad metal layer 175 are formed in the same manner as the metal layer 130, an additional mask is not required. However, the ROM interface pad 150 and the via contact 160 can be separately formed according to an embodiment of the present invention.

The inter-metal insulating layer 140, comprising an insulating material and formed on the pad metal layer 175, the metal layer 130 and the test pad metal layer 165, is generally formed as a passivation layer. According to an embodiment of the present invention, an inter-metal insulating layer can be used. During assembly of the semiconductor device 100, the inter-metal insulating layer 140 protects the layers 130 and 120 below the inter-metal insulating layer 140.

The pad region includes the pad metal layer 175. The pad region 170 is a path for transferring power control signal(s) and input/output data from the outside of the semiconductor device 100. The pad metal layer 175 is a portion where bonding wires are directly attached during the assembly of the semiconductor device 100. Because the ROM interface pad 150 is used only to validate test data, the size and electrical characteristics of the pad region 170 are substantially different from those of the ROM interface pad 150. When assembling the semiconductor device 100, if the area of the pad region 170 is approximately 200 μm×approximately 60 μm, the ROM interface pad 150 may have a size of approximately 20 μm×approximately 20 μm. In other words, the ROM interface pad 150 may be formed using about 1/30 of a chip surface area used by the pad region 170.

The test circuit region 180 is formed on the multilayer 120, receives test data stored in a predetermined data storage device (not shown) located outside of the semiconductor device 100, and transfers the test data to a processor (not shown). To form the test circuit region 180, an additional mask is used.

According to an embodiment of the present invention, a semiconductor device used in a test stage can be manufactured using two additional masks, a metal process and a contact hole forming process. The two additional masks include a via contact mask and a ROM interface pad mask. The contact hole forming process is a process for forming the hole in the inter-metal insulating layer 140, and includes an etching process using the contact hole mask. The metal process includes a metal depositing process and a metal etching process using the ROM interface pad mask.

The inter-metal insulating layer 140 covers the entire semiconductor device 100 except for the pad region 170 for transferring, e.g., power control signal(s) and input/output data, and may comprise, for example, an oxide layer or a nitride layer.

Although the ROM interface pad 150 may be disposed in a region not occupied by a pattern formed by a circuit performing a function of the semiconductor device 100, the ROM interface pad 150 can be disposed on a region occupied by patterns formed by the circuit performing a function of the semiconductor device 100 according to an embodiment of the present invention.

When wires are bonded to the ROM interface pad 150, electrical shock or static charge can reach a pattern located at the bottom portion of the ROM interface pad 150, possibly rendering changes to the electrical characteristics of the pattern. In such instance, a low defect rate cannot be ensured during mass-production. Some semiconductor chips in a wafer can endure the electric shock and the static charges. These semiconductor chips can be used in the verification of command codes. According to an embodiment of the present invention, the ROM interface pad 150 is removed and bonding wires are not attached thereon when the semiconductor device 100 is mass-produced.

FIG. 2 is a perspective view of the semiconductor device 100 in FIG. 1.

Referring to FIG. 2, the pads 170-1 through 170-10 formed on the semiconductor device 100 are used for performing a function of the semiconductor device 100, and the ROM interface pads 150-1 through 150-12 disposed on the semiconductor device 100 are used in a test stage.

The pads 170-1 through 170-10 located under the insulating layer 140 correspond to the pad region 170 shown in FIG. 1, and the ROM interface pads 150-1 through 150-12 disposed on the insulating layer 140 correspond to the ROM interface pad 150 shown in FIG. 1. Although the ROM interface pad 150 is used in the validation of test data in a test stage, it is removed from the assembled components in the mass-production stage.

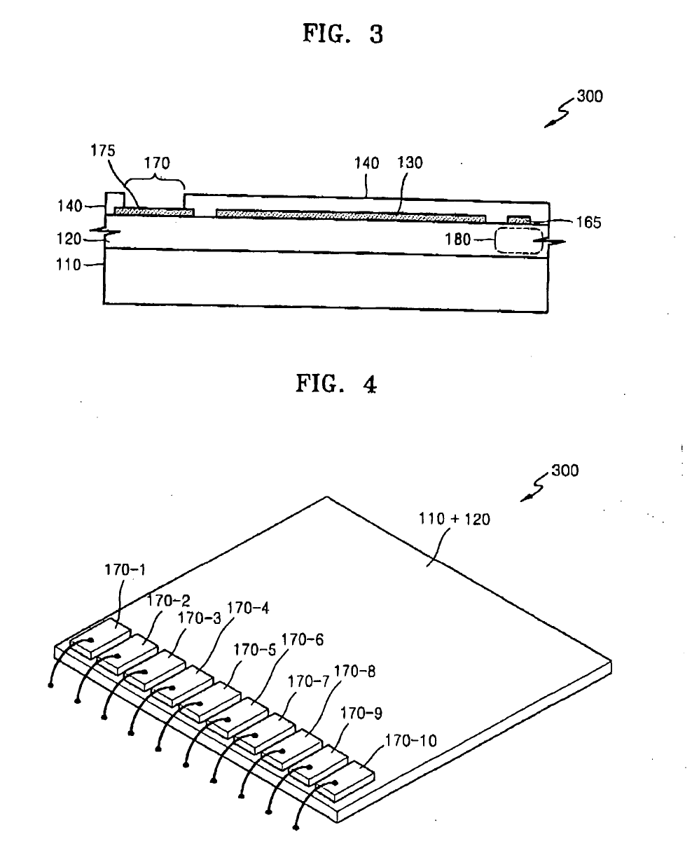

FIG. 3 is a sectional view illustrating a vertical structure of a semiconductor device 300 in a mass-production stage according to an embodiment of the present invention.

Referring to FIG. 3, the semiconductor device 300 includes the substrate 110, the multilayer 120, the metal layer 130, the inter-metal insulating layer 140, the pad region 170, and the test circuit region 180.

When compared to the vertical sectional diagram in the test stage illustrated in FIG. 1, the sectional view illustrated in FIG. 3 does not include the ROM interface pad 150 and the via contact 160.

FIG. 4 is a perspective view of the semiconductor device 300 in FIG. 3. When compared to the perspective view of the semiconductor device 100 in a test stage illustrated in FIG. 2, the semiconductor device 300 in a mass-production stage illustrated in FIG. 4 does not include the ROM interface pads 150-1 through 150-12. Therefore, the via contacts that are located beneath the ROM interface pads 150-1 through 150-12 are also omitted from FIG. 4.

In the test stage, the ROM interface pad 150 and the via contact 160 are manufactured to be included in a semiconductor device for verifying test data stored in an external memory device. However, in the mass-production stage, because the ROM interface pad 150 and the via contact 160 used in the test stage are removed, masks and processes used to create the ROM interface pad 150 and the via contact 160 are not needed.

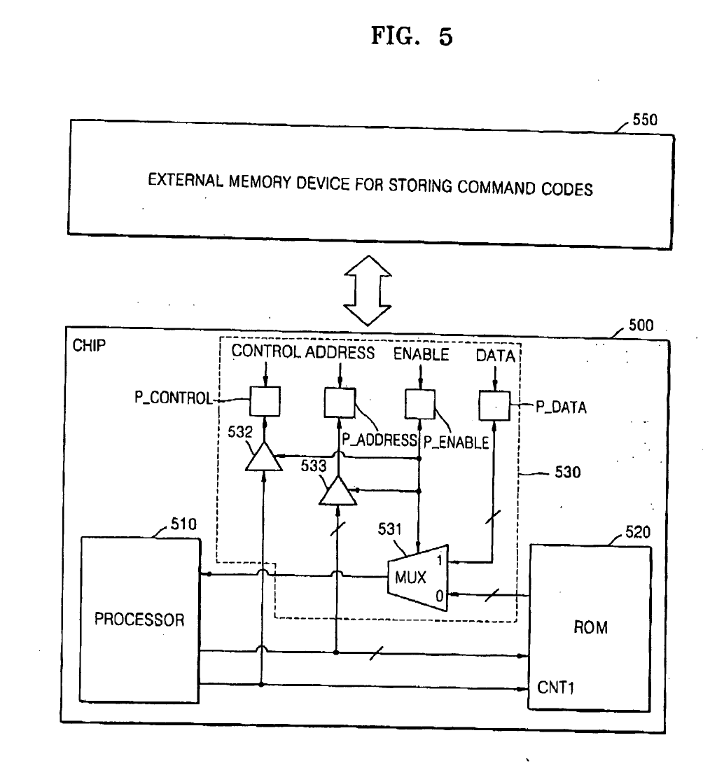

FIG. 5 is a circuit diagram used to test the semiconductor device 100 shown in FIG. 1 in a test stage according to an embodiment of the present invention. In an embodiment, the test circuit region 180 of the semiconductor device 100 in FIGS. 1 and 2 is used to verify test data stored in a memory device formed outside of the semiconductor device 100.

Referring to FIG. 5, a semiconductor device 500 includes a processor 510, a memory device 520, and a test circuit block 530. An external memory device 550 for storing command codes DATA is formed outside of the semiconductor device 500.

The processor 510 outputs an address signal ADDRESS and a control signal CONTROL for requesting command codes DATA stored in a predetermined storage device 550 located outside of the semiconductor device 500 or in an internally-installed memory device 520 through the test circuit block 530. The requested command codes DATA are received through the test circuit block 530, and commands included in the received command codes DATA are implemented.

The memory device 520 transfers the stored command codes to the test circuit block 530 in response to the address signal and control signal from the processor 510. When the semiconductor device 500 is used in a non-test manner by a user, the semiconductor device 500 operates in response to the command codes stored in the memory device 520. The command codes outputted from the memory device 520 are transferred to the processor 510 through the test circuit block 530.

The test circuit block 530 includes a first transfer device 532 and a second transfer device 533 for transferring a control signal CONTROL and an address signal ADDRESS received from the processor 510 to the external memory device 550, and a multiplexer 531 that selects and outputs either a command code DATA for verification transferred from the external memory device 550 or a command code transferred from the memory device 520. The first transfer device 532, the second transfer device 533, and the multiplexer 531 operate in response to a test enable signal ENABLE. The address signal ADDRESS, control signal CONTROL, command code DATA, and enable signal ENABLE are respectively inputted/outputted through address, control, data, and enable pads P_ADDRESS, P_CONTROL, P_DATA, and P_ENABLE. The test circuit block 530 corresponds to the circuit installed on the test circuit region 180 in FIG. 1.

The operation of the test circuit block 530 in response to the test enable signal ENABLE according to an embodiment of the present invention is described below.

If the test enable signal ENABLE indicates a test stage, the first and second transfer devices 532 and 533 respectively transfer a control signal CONTROL and an address signal ADDRESS to the external memory device 550, and the multiplexer 531 transfers the command codes DATA transferred from the external memory device 550 to the processor 510. According to an embodiment of the present invention, because the control signal CONTROL and the address signal ADDRESS are simultaneously transferred to the memory device 520, the requested command codes are transferred from the memory device 520 to the test circuit block 530. However, the transfer from the memory device 520 to the processor 510 is blocked by the multiplexer 531.

If the test enable signal ENABLE does not indicate the test stage, outputs of the first and the second transfer devices 532 and 533 become a high impedance state, and the multiplexer 531 transfers the data outputted from the memory device 520 to the processor 510. That the test enable signal ENABLE does not indicate the test stage means a mass-production stage. In the mass-production stage, because the test enable pad P_ENABLE is not formed, there is no test enable signal ENABLE. In the mass-production state, the first and second transfer devices 532 and 533 that transfer an address signal ADDRESS and a control signal CONTROL are not used. For the multiplexer 531, if the test enable signal ENABLE becomes inactive, a selection of a command code transferred from the internally-installed memory device 520 is required.

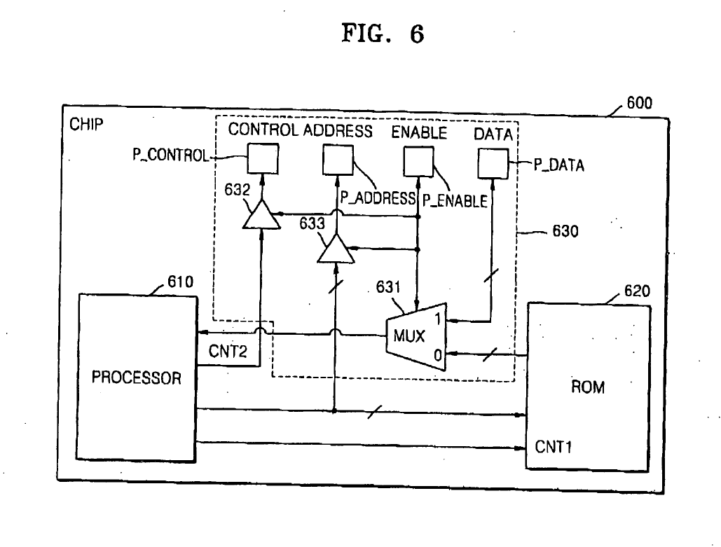

FIG. 6 is a circuit diagram used to test the semiconductor device 100 shown in FIG. 1 in a test stage according to an embodiment of the present invention.

Referring to FIG. 6, the semiconductor device 600 includes a processor 610, a memory device 620, and a test circuit block 630. According to this embodiment of the present invention, the semiconductor device 600 in FIG. 6 separates and uses a control signal CNT1 transferred to the internally-installed memory device 620 and a control signal CNT2 transferred to an external memory device (not shown) for storing command codes DATA.

The verification of command codes stored in the external memory device can be performed using the semiconductor device in an unassembled state or in an assembled state.

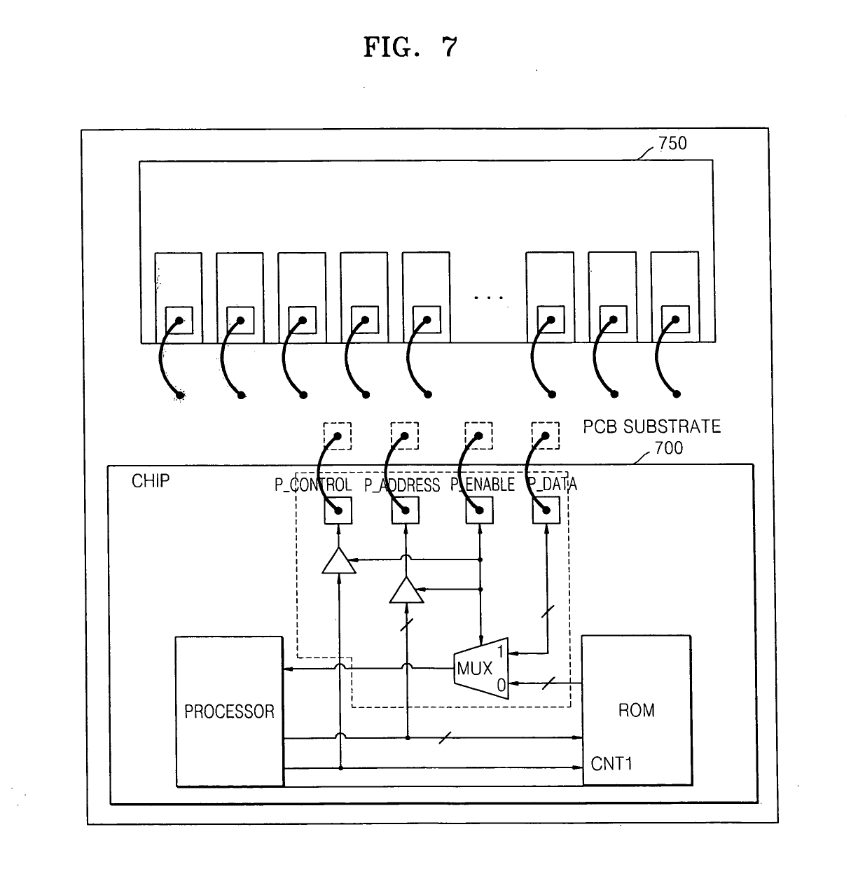

FIG. 7 is a circuit diagram illustrating a PCB used to verify command codes when a semiconductor device 700 is not yet assembled according to an embodiment of the present invention.

Referring to FIG. 7, when the semiconductor device 700 is used in an unassembled state, control, address, enable, and data pads P_CONTROL, P_ADDRESS, P_ENABLE and P_DATA of the open semiconductor device 700 are connected by wires directly to predetermined connecting points (dotted squares) on the PCB. The pads of an external memory device 750 for storing command codes in FIG. 7 are connected by wires directly to other predetermined connecting points on the PCB. According to an embodiment of the present invention, the external memory device 750 may also be attached to the PCB and used in a packaged state.

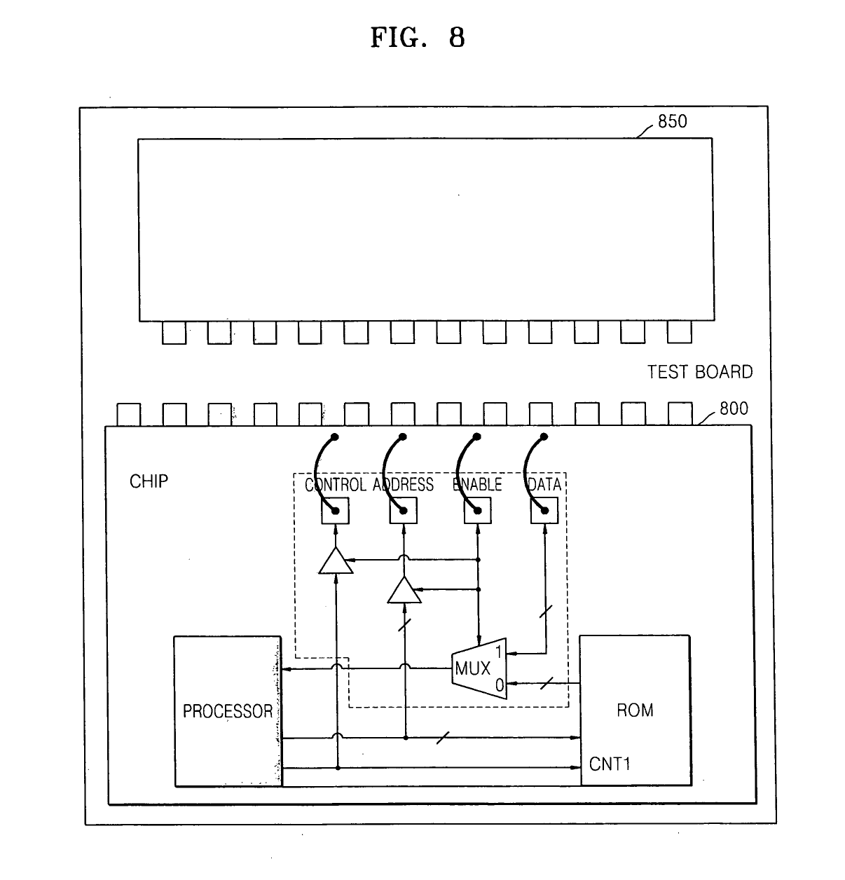

FIG. 8 is a circuit diagram illustrating a PCB used to verify command codes for a semiconductor device 800 in an assembled state according to an embodiment of the present invention.

Referring to FIG. 8, because the semiconductor device 800 is assembled in a package state, the PCB generally includes a socket (not shown) mounting the semiconductor device 800. Accordingly, the pads of the semiconductor device 800 are connected to a lead frame through wires. The external memory device 850 for storing command codes in FIG. 8 is attached to the PCB in a packaged state. According to an embodiment of the present invention, the external memory device 850 may also be used in an unassembled state.

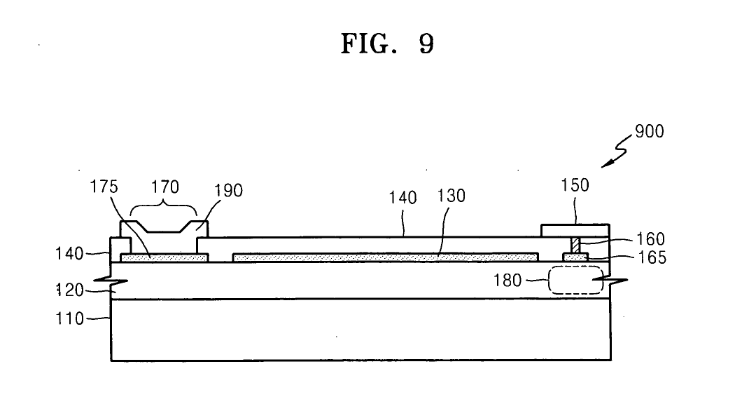

FIG. 9 is a sectional view illustrating a vertical structure of a semiconductor device including a ROM interface pad in a test stage according to another embodiment of the present invention.

FIG. 9 illustrates a vertical section of a semiconductor device 900 including the metal layer 130, the test pad metal layer 165, and the pad metal layer 175. When copper is used for the layers 130, 165, and 175, the low degree of adhesiveness between the pad metal layer 175 and bonding wires during assembly may occur. According to an embodiment of the present invention, the pad region 170 includes the pad metal layer 175 and an aluminium layer 190. The aluminium layer 190 is formed on the pad metal layer 175 to cure, for example, the low degree adhesion problem. In this case, the test pad metal layer 165 and the aluminium layer 190 may be formed using a known mask.

In mass-production, the test pad metal layer 165 can be removed by a new mask. If the test circuit formed on the test circuit region 180 is controlled to maintain a disabled state, the operation of the chip is unaffected by noise components applied through the test pad metal layer 165 even if assembly is performed without removing the test pad metal layer 165. According to an embodiment of the present invention, the manufacturing cost can be reduced because a new mask and additional fabricating processes are not required.

According to an embodiment of the present invention, processes such as, for example, revising a ROM code mask after developing command codes, implementing a fabrication process based on the new command codes, and validating the new command codes can be omitted.

According to an embodiment of the present invention, a verification of the performance or operation of the changed or newly developed command codes can be performed with a chip to be used by the command codes. Also, by applying the final verified command codes to an actual mask revision, the manufacturing cost, time, and manpower for code development can be substantially reduced, and an evaluation chip used for verification in code development projects is no longer needed. A loss of chips usable in a wafer can be reduced because an uppermost metal layer is not used and a via contact after verification of command codes is completed. Furthermore, because the metal layer for a test pad and a via contact are used only for forming verifying pads for command codes, a mask with lower level of precision can be used.

Although the exemplary embodiments of the present invention have been described with reference to the accompanying drawings, it is to be understood that the present invention should not be limited to these precise embodiments but various changes and modification can be made by one ordinary skill in the art without departing from the spirit and scope of the present invention. All such changes and modification are intended to be included with the scope of the invention as defined by the appended claims.

What is claimed is:

1. A semiconductor device comprising:
a multilayer formed on a semiconductor substrate, the multilayer including a first circuit pattern;
a second circuit pattern for testing the semiconductor device, the second circuit pattern formed on a predetermined region of the multilayer;
an inter-metal insulating layer formed on the second circuit pattern;
a plurality of via contacts formed in the inter-metal insulating layer; and
a plurality of ROM interface pads disposed on the inter-metal insulating layer, wherein the plurality of ROM interface pads are electrically connected with the second circuit pattern through the plurality of via contacts, and are separated from one another.

2. The semiconductor device of claim 1, wherein the semiconductor device including the plurality of via contacts and the plurality of ROM interface pads is used in a test stage, and the plurality of via contacts and the plurality of ROM interface pads are removed thereafter.

3. The semiconductor device of claim 1, wherein the inter-metal insulating layer covers the semiconductor device except for a plurality of pads for receiving a voltage, a control signal, and input/output data.

4. The semiconductor device of claim 3, wherein the inter-metal insulating layer is one of an oxide layer and a nitride layer.

5. The semiconductor device of claim 1, wherein the ROM interface pads are disposed on a region occupied by the first circuit patterns.

6. The semiconductor device of claim 1, wherein the ROM interface pads are disposed on a region not occupied by the first circuit patterns.

7. A semiconductor device comprising:
a processor unit formed using a plurality of layers on a substrate;
a test circuit block formed using the plurality of layers, the test circuit block receiving test data from a predetermined data storage device located outside of the semiconductor device and transferring the test data to the processor unit;
an inter-metal insulating layer formed on the test circuit block, the inter-metal insulating layer comprising a plurality of via contacts;
a first plurality of pads for receiving a voltage, a control signal, and input/output data; and
a second plurality of pads disposed on the inter-metal insulating layer, wherein the second plurality of pads are electrically connected to the test circuit block through the plurality of via contacts, and are separated from one another.

8. The semiconductor device of claim 7, wherein the semiconductor device including the plurality of via contacts and the second plurality of pads is used in a test stage, and the plurality of via contacts and the second plurality of pads are removed thereafter.

9. The semiconductor device of claim 7, wherein the test circuit block comprises:
at least one multiplexer receiving a test enable signal for operating the semiconductor device in the test stage, and selecting test data and data created in the semiconductor device and transferring the selected data to the processor unit;
a first transfer device transferring a control signal to the predetermined data storage device, wherein the control signal is outputted by the processor unit and controls an operation of the predetermined data storage device; and
a second transfer device transferring an address signal for designating an address for the predetermined data storage device storing the predetermined test data,
wherein the multiplexer, the first transfer device, and the second transfer device operate in response to the test enable signal.

10. The semiconductor device of claim 9, wherein the multiplexer selects and outputs the test data when the test enable signal indicates the test stage, and selects and outputs data created in the semiconductor device including the second plurality of pads when the test enable signal does not indicate the test stage.

11. The semiconductor device of claim 9, wherein the first transfer device and the second transfer device transfer the control signal and the address signal to the predetermined storage device when the test enable signal indicates the test stage, and the first transfer device and the second transfer device are in a high impedance state when the test enable signal does not indicate the test stage.

12. The semiconductor device of claim 9, wherein the predetermined data storage device is a read only memory (ROM).

13. The semiconductor device of claim 9, further comprising a memory device generating the data created in the semiconductor device.

14. The semiconductor device of claim 13, wherein the memory device is a read only memory (ROM).

15. The semiconductor device of claim 9, wherein the test enable signal is generated in the semiconductor device or is received from the outside of the semiconductor device.

16. The semiconductor device of claim 9, wherein the inter-metal insulating layer covers the semiconductor device except for the first plurality of pads.

17. The semiconductor device of claim 16, wherein the inter-metal insulating layer is an oxide layer or a nitride layer.

18. The semiconductor device of claim 7, wherein the second plurality of pads are disposed on a region occupied by patterns for forming a circuit for performing functions of the semiconductor device.

19. The semiconductor device of claim 7, wherein the second plurality of pads are disposed on a region not occupied by patterns for forming a circuit for performing functions of the semiconductor device.

20. A test printed circuit board (PCB) comprising:
an external memory device storing command codes to be verified; and
a semiconductor device comprising a processor device receiving the command codes of the external memory device and validating the command codes,
wherein the semiconductor device and the external memory device are mounted on the test PCB, and the external memory device is electrically connected to the test PCB.

21. The test PCB of claim 20, wherein the semiconductor device and the external memory device are mounted on the test PCB in an unassembled state.

22. The test PCB of claim 20, wherein the semiconductor device and the external memory device are mounted on the test PCB in an assembled state.

23. The test PCB of claim 21, wherein the semiconductor device and the external memory device are electrically connected to the test PCB through a wire bonding when mounted in the unassembled state.

24. The test PCB of claim 22, wherein the semiconductor device and the external memory device are electrically connected to the test PCB through a socket when mounted in the assembled state.

25. A semiconductor device comprising:
a multilayer formed on a semiconductor substrate, the multilayer including a first circuit pattern for performing a predetermined function;
a second circuit pattern for testing the semiconductor device formed on a predetermined region of the multilayer;
an inter-metal insulating layer formed on the second circuit pattern;
a plurality of via contacts formed on the inter-metal insulating layer;
a first metal layer formed on a pad metal layer in a pad region; and
a plurality of ROM interface pads disposed on the inter-metal insulating layer, wherein the ROM interface pads are electrically connected to the second circuit pattern through the plurality of via contacts, and separated from one another.

26. The semiconductor device of claim 25, wherein the pad metal layer and the first metal layer comprise different materials.

27. The semiconductor device of claim 25, wherein the pad metal layer includes copper and the first metal layer includes aluminum.

28. The semiconductor device of claim 26, wherein the first metal layer and the ROM interface pads are formed using a same material.

29. The semiconductor device of claim 26, wherein the first metal layer and the ROM interface pads are formed using a common mask.
